(19) United States
(12) Patent Application Publication
(10) Pub. No.: US 2006/0063346 A1
(43) Pub. Date: Mar. 23, 2006

(54) Method of forming a layer and method of forming a capacitor of a semiconductor device having the same

(76) Inventors: Jong-Cheol Lee, Seoul (KR); Ki-Vin Im, Suwon-si (KR); Sung-Tae Kim, Seoul (KR); Young-Sun Kim, Suwon-si (KR); Cha-Young Yoo, Suwon-si (KR); Han-Mei Choi, Seoul (KR); Gab-Jin Nam, Seoul (KR)

Correspondence Address: F. CHAU & ASSOCIATES, LLC, 130 WOODBURY ROAD, WOODBURY, NY, 11797, US

(21) Appl. No.: 11/149,708

(22) Filed: Jun. 10, 2005

(30) Foreign Application Priority Data
Jun. 10, 2004 (KR) 2004/42551

(51) Int. Cl. H01L 21/20

(52) U.S. Cl. 438/393

(57) ABSTRACT

In a method of forming a layer using an atomic layer deposition process, after a substrate is loaded into a chamber, a reactant is provided onto the substrate to form a preliminary layer. Atoms in the preliminary layer are partially removed from the preliminary layer using plasma formed from an inert gas such as an argon gas, a xenon gas or a krypton gas, or an inactive gas such as an oxygen gas, a nitrogen gas or a nitrous oxide gas to form a desired layer. Processes for forming the desired layer may be simplified. A highly integrated semiconductor device having improved reliability may be economically manufactured so that time and costs required for the manufacturing of the semiconductor device may be reduced.

### CROSS-REFERENCE TO RELATED APPLICATION

This application claims priority under 35 USC § 119 to Korean Patent Application No. 2004-42551 filed on Jun. 10, 2004, the content of which is incorporated herein by reference in its entirety.

### BACKGROUND OF THE INVENTION

1. Field of the Invention

Exemplary embodiments of the present invention relate to methods of forming a layer and methods of forming a capacitor having the layer. More particularly, exemplary embodiments of the present invention relate to methods of forming a layer using an atomic layer deposition (ALD) process and methods of forming a capacitor having the layer.

2. Description of the Related Art

Since the trend in the art requires semiconductor devices to have high storage capacity and high response speed, semiconductor manufacturing technology has been developed to improve the degree of integration, reliability and response speed of the semiconductor devices.

Dynamic random access memory (DRAM) devices are widely used for various electric or electronic apparatuses because the DRAM devices have high storage capacity and high degree of integration. Generally, the memory cell of the DRAM device includes one access transistor and one storage capacitor. As the degree of integration for the memory cell of the DRAM device increases, the memory cell occupies a smaller area on a semiconductor substrate.

As semiconductor devices become more highly integrated, processing conditions for forming a layer of a semiconductor device, such as having a low heat budget, good step coverage, precise control of a thickness of the layer, a low-contaminated environment, etc., necessarily become more stringent.

Conventional chemical vapor deposition (CVD) processes, such as a low-pressure chemical vapor deposition (LPCVD) process and a plasma-enhanced chemical vapor deposition (PECVD) process may not be suitable for forming a layer of a highly integrated semiconductor device. For example, a layer is formed at a relatively high temperature in the conventional CVD process, which severely deteriorates the characteristics of a semiconductor device due to the high heat budget and the redistribution of dopants. In addition, the layer formed on a substrate by a conventional CVD process may have uneven thickness, thereby causing a loading effect on the semiconductor device. That is, the portion of the layer positioned on densely arranged underlying structures has a thickness substantially thinner than that of other portions of the layer formed on sparsely arranged underlying structures, which causes a loading effect on the semiconductor device.

A layer formed through a conventional LPCVD process may have a relatively high content of impurities such as hydrogen, and may also have poor step coverage. Likewise, when a conventional PECVD process is used to form a layer of a semiconductor device, the layer may have poor step coverage even though the layer may have been formed at a relatively low temperature in comparison with the layer formed through the conventional LPCVD process.

Considering the above-mentioned problems, an atomic layer deposition (ALD) process has been developed because a layer of a semiconductor device having good step coverage may be formed at a relatively low temperature without having a loading effect thereon.

The atomic layer deposition process includes a step for providing a metal precursor to a chamber, a step for introducing an inactive gas to purge the chamber, and a step for providing an oxidizing agent such as oxygen (O₂), ozone (O₃), and water vapor (H₂O) to the chamber. Particularly, the metal precursor is chemically and/or physically absorbed onto a substrate, and a physisorbed metal precursor is removed from the chamber by purging the chamber. Then, the oxidizing agent is provided onto a chemisorbed metal precursor to form a desired oxide layer.

FIGS. 1A to 1D are cross sectional views illustrating a method of forming a layer using a conventional ALD process.

Referring to FIG. 1A, a first reactant 20 is provided onto a substrate 12 in a chamber 10 to chemisorb the first reactant 20 to the substrate 12.

Referring to FIG. 1B, a first purge gas is introduced into the chamber 10 to remove a non-chemisorbed first reactant 20 from the chamber 10. The non-chemisorbed first reactant 20 may include a physisorbed first reactant 20 to the substrate 12.

Referring to FIG. 1C, a second reactant 22 is subsequently introduced into the chamber 10 so that the second reactant 22 is reacted with the chemisorbed first reactant 20.

Referring to FIG. 1D, a second purge gas is introduced into the chamber 10 to remove an unreacted second reactant 22 from the chamber 10. Accordingly, a desired layer 24 with a reduced amount of impurities thereof is formed on the substrate 12.

For example, U.S. Pat. No. 6,124,158 (issued to Dautartas. et al.) discloses a method of forming a thin layer by employing an ALD process. In the method of the above U.S. Pat. No. 6,124,158, a first reactant is introduced onto a substrate in a chamber to form a monolayer on the substrate. Then, a second reactant is introduced onto the monolayer to form a desired thin layer on the substrate by reacting the second reactant with the monolayer. The chamber is purged using an inert gas before and after introducing the second reactant, thereby effectively preventing the reaction of the first reactant and/or the second reactant except for the surface of the substrate.

In addition, Korean Patent Application No. 2001-38641 discloses a method of forming a metal oxide layer or a metal nitride layer by employing an ALD process. In the method of the above Korean Patent Application No. 2001-38641, a tantalum oxide layer is formed using an atomic layer deposition process. Simultaneously, the tantalum oxide layer is repeatedly treated with ozone plasma several times.

However, forming metal oxide layer or the metal nitride layer using the conventional ALD process, requires a subsequent addition of an oxidizing agent or a nitrifying agent into the chamber after introducing the metal precursor. In addition, forming metal oxynitride layer by the conventional ALD process may require additional nitrification processes or oxidization processes. Thus, a simplified ALD process is required to economically form the metal oxide layer, the metal nitride layer or the metal oxynitride layer, a simplified ALD process is required.

### SUMMARY OF THE INVENTION

The present invention provides a method of forming a layer by employing a simplified atomic layer deposition process.

The present invention also provides a method of forming a capacitor including the layer.

In accordance with one embodiment of the present invention, there is provided a method of forming a layer. In the method, after forming a preliminary layer of atoms on a substrate by an atomic layer deposition (ALD) process, a portion of atoms is removed from the preliminary layer using plasma formed from a gas. The plasma may be generated adjacent to the substrate.

Particularly, the gas for forming the plasma is introduced into the chamber, and then the gas is excited to induce a plasma phase so that the plasma is generated. Alternatively, the plasma may be generated separately from the substrate. In particular, the plasma is formed outside of the chamber, and then the plasma is introduced into the chamber.

According to an exemplary embodiment of the present invention, a reactant such as an organic metal precursor is chemisorbed to the substrate, and then a portion of atoms is removed from a chemisorbed reactant using the plasma formed from an inert gas, an inactive gas or a mixture thereof to form a layer including metal, metal oxide, or metal oxynitride.

According to an exemplary embodiment of the present invention, a substrate is loaded into a chamber. A reactant is introduced into the chamber, and then the reactant is chemisorbed to the substrate to form a preliminary layer on the substrate. A portion of atoms is partially or completely removed from the preliminary layer using plasma.

According to an exemplary embodiment of the present invention, a substrate is loaded into a chamber. A first reactant is introduced into the chamber, and then the first reactant is chemisorbed to the substrate to form an absorption layer on the substrate. A portion of atoms is partially or completely removed from the absorption layer using plasma to form a preliminary layer. A second reactant is introduced into the chamber to form a layer on the substrate.

In accordance with another exemplary embodiment of the present invention, there is provided a method of forming a capacitor of a semiconductor device. In the method, a substrate including a lower electrode is loaded into a chamber. A reactant is provided onto the substrate to form a preliminary layer on the lower electrode. A portion of atoms is removed from the preliminary layer to form a dielectric layer on the lower electrode. An upper electrode is then formed on the dielectric layer.

According to an exemplary embodiment of the present invention, a substrate including a lower electrode is loaded into a chamber. A first reactant is provided onto the substrate to form an absorption layer on the lower electrode. A portion of atoms is removed from the absorption layer to form a preliminary layer. A second reactant is provided onto the preliminary layer to form a dielectric layer on the lower electrode. An upper electrode is formed on the dielectric layer.

According to the present invention, a plasma is provided to a preliminary layer formed using an atomic layer deposition process to remove a portion of atoms from the preliminary layer. Hence, a desired layer may be economically formed from the preliminary layer.

Thus, processes for forming the desired layer may be simplified. As a result, a highly integrated semiconductor device having improved reliability may be economically manufactured to reduce the time and costs required for the manufacturing of a semiconductor device.

### BRIEF DESCRIPTION OF THE DRAWINGS

Exemplary embodiments of the present invention will become readily apparent by reference to the following detailed descriptions when considered in conjunction with the accompanying drawings, wherein:

FIGS. 1A to 1D are cross sectional views illustrating a method of forming a layer using a conventional atomic layer deposition process;

FIG. 2 is a cross sectional view illustrating an apparatus for forming a layer using an atomic layer deposition process in accordance with an exemplary embodiment of the present invention;

FIGS. 3A to 3C are cross sectional views illustrating a method of forming a layer using the apparatus in FIG. 2;

FIGS. 4A to 4E are cross sectional views illustrating a method of forming a layer using the apparatus in FIG. 2;

FIG. 5 is a cross sectional view illustrating an apparatus for forming a layer using an atomic layer deposition process in accordance with an exemplary embodiment of the present invention;

FIGS. 6A to 6C are cross sectional views illustrating a method of forming a layer using the apparatus in FIG. 5;

FIGS. 7A to 7E are cross sectional views illustrating a method of forming a layer using the apparatus in FIG. 5;

FIGS. 8A to 8E are cross sectional views illustrating a method of forming a capacitor in accordance with an exemplary embodiment of the present invention;

FIG. 9 is a graph illustrating an oxygen content of a hafnium oxynitride layer obtained using a photoelectron spectroscopy method in accordance with an embodiment of the present invention;

FIG. 10 is a graph illustrating a nitrogen content of a hafnium oxynitride layer obtained using a photoelectron spectroscopy method in accordance with an embodiment of the present invention; and

FIG. 11 is a graph illustrating contents of a hafnium-oxygen bond and a hafnium-nitrogen bond in a hafnium oxynitride layer obtained using a photoelectron spectroscopy method in accordance with an embodiment of the present invention.

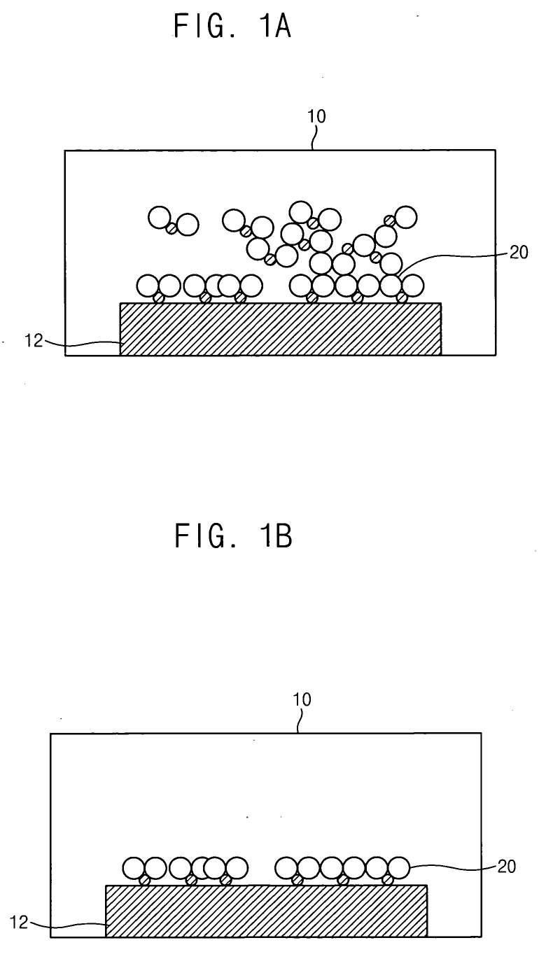

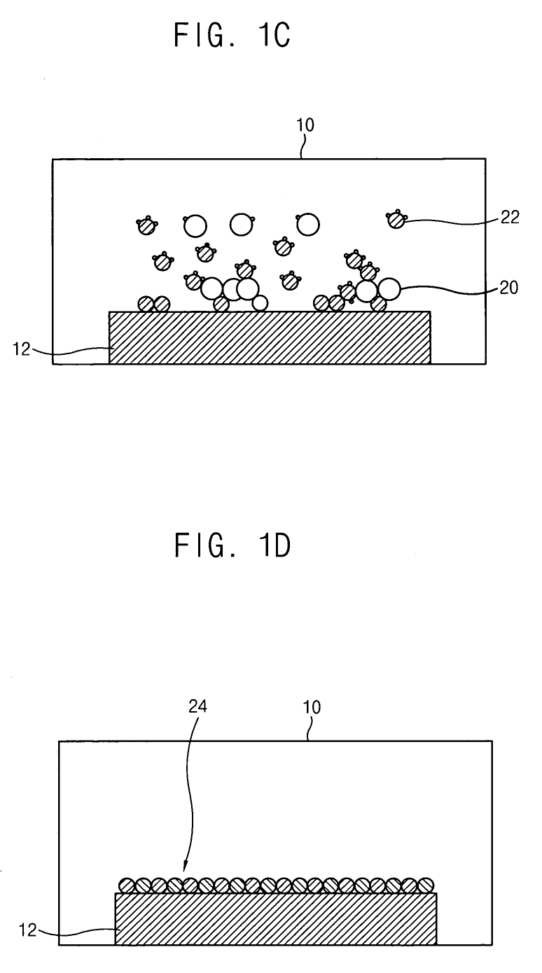

### DESCRIPTION OF PREFERRED EMBODIMENTS

Exemplary embodiments of the present invention now will be described more fully hereinafter with reference to the accompanying drawings. In the drawings, the thickness of layers and regions are exaggerated for clarity. Like reference numerals refer to similar or identical elements throughout. It will be understood that when an element such as a layer, region or substrate is referred to as being “on” or “onto” another element, it can be directly on the other element or intervening elements may also be present.

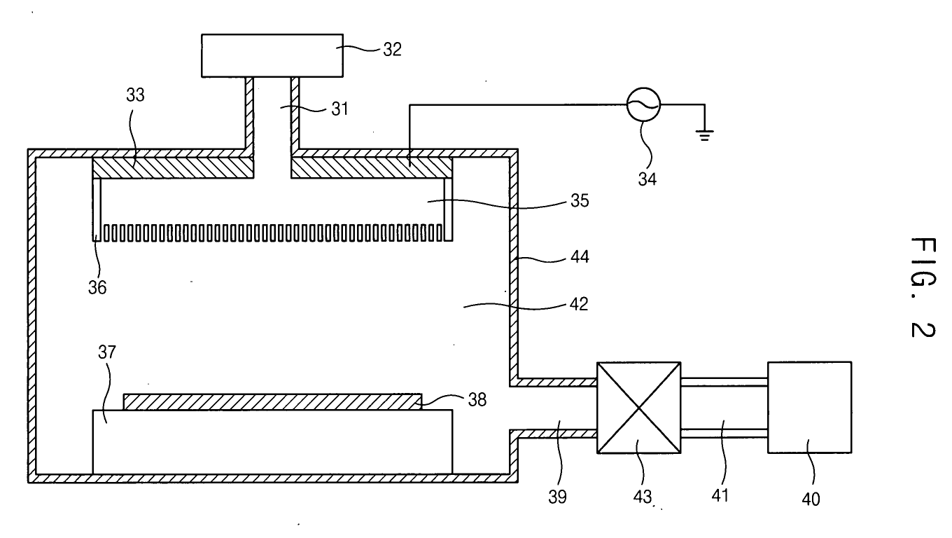

FIG. 2 is a cross sectional view illustrating an apparatus for forming a layer using an atomic layer deposition (ALD) process in accordance with an exemplary embodiment of the present invention.

Referring to FIG. 2, the apparatus for forming the layer includes a chamber 44 having a reaction space 42 provided therein.

A gas inlet 31 is connected to an upper portion of the chamber 44, and a gas supply member 32 is connected to the gas inlet 31. The gas supply member 32 provides a reactant and a purge gas into the reaction space 42.

An electrode 33 is installed beneath an inner upper face of the chamber 44, and a radio frequency (RF) power source 34 is electrically connected to the electrode 33. The RF power source 34 applies a radio frequency (RF) power to the electrode 33 so that the electrode 33 excites a gas to form a plasma in a buffer space 35.

A showerhead 36 is installed under the electrode 33 to uniformly provide the plasma onto a substrate 38 positioned on a chuck 37. The buffer space 35 is provided between the showerhead 36 and the electrode 33.

A gas outlet 39 is connected to one lower side of the chamber 44, and a pump 40 is connected to the gas outlet 39 through an exhaust pipe 41. A pressure control valve 43 is installed between the gas outlet 39 and the pump 40.

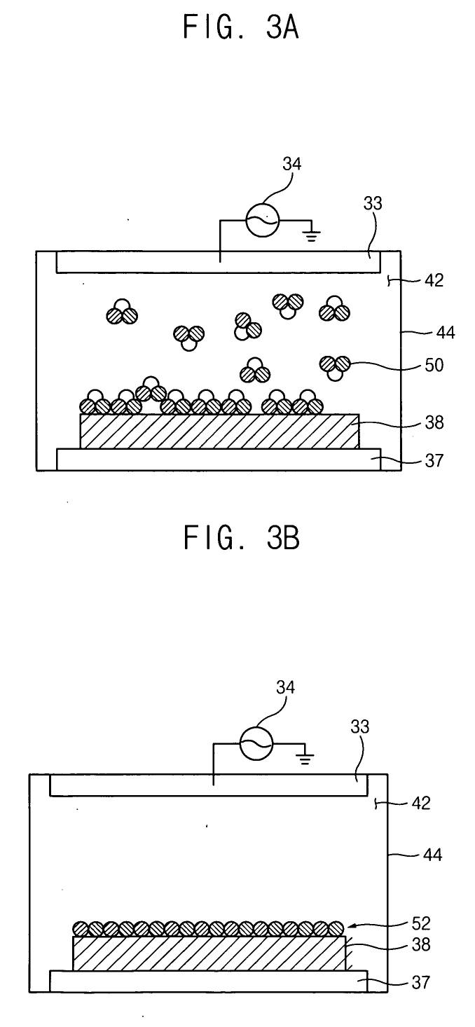

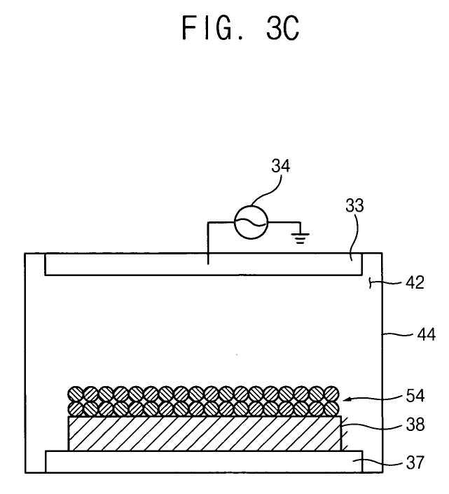

FIGS. 3A to 3C are cross sectional views illustrating a method of forming a layer using the apparatus in FIG. 2 in accordance with an exemplary embodiment of the present invention.

Referring to FIGS. 2, and 3A, after the substrate 38 is loaded onto the chuck 37 installed in the chamber 44, a reactant 50 or a gas including the reactant 50 is introduced into the reaction space 42 through the gas inlet 31.

The reactant 50 may include an organic precursor such as an organic metal precursor. Here, the reactant 50 may include a metal, and a ligand or an atomic group. Examples of the organic precursor may include an alkoxide compound, an amino compound, a cyclopentadienyl compound, a diketonate compound, an alkyl compound, etc. These can be used alone or in a mixture thereof.

Examples of the alkoxide compound may include B[OCH₃]₃, B[OC₂H₅]₃, Al[OCH₃]₃, Al[OC₂H₅]₃, Al[OC₃H₇]₃, Ti[OCH₃]₄, Ti[OC₂H₅]₄, Ti_{[OC}₃H₇]₄, Zr[OC₃H₇]₄, Zr[OC₄H₉]₄, Zr[OC₄H₈OCH₃]₄, Hf[OC₄H₉]₄, Hf[OC₄H₈OCH₃]₄, Hf[OSi(C₂H₅)₃]₄, Hf[OC₂H₅]₄, Hf[OC₃H₇]₄, Hf[OC₄H₉]₄, Hf[OC₅H₁₁]₄, Si[OCH₃]₄, Si[OC₂H₅]₄, Si[OC₃H₇]₄, Si[OC₄H₉]₄, HSi[OCH₃]₃, HSi[OC₂H₅]₃, Si[OCH₃]₃F, Si[OC₂H₅]₃F, Si[OC₃H₇]₃F, Si[OC₄H₉]₃F, Sn[OC₄H₉]₄, Sn[OC₃H₇]₃[C₄H₉], Pb[OC₄H₉]₄, Pb₄O[OC₄H₉]₆, Nb[OCH₃]₅, Nb[OC₂H₅]₅, Nb[OC₃H₇]₅, Nb[OC₄H₉]₅, Ta[OCH₃]₅, Ta[OC₂H₅]₅, Ta[OC₄H₉]₅, Ta_{OC}₂H₅]₅, Ta[OC₂H₅]₅[OC₂H₄N(CH₃)₂], P[OCH₃]₃, P[OC₂H₅]₃, P[OC₃H₇]₃, P[OC₄H₉]₃ and PO[OCH₃]₃. These can be used alone or in a mixture thereof.

Examples of the amino compound may include Hf(NCH₃CH₃)₄, Hf(NCH₃C₂H₅)₄, Hf(NC₂H₅C₂H₅)₄, Hf(NCH₃C₃H₇)₄, Hf(NC₂H₅C₃H₇)₄ and Hf(NC₃H₇C₃H₇)₄. These can be used alone or in a mixture thereof.

Examples of the cyclopentadienyl compound may include Ru(Cp)₂ (wherein, “Cp” represents a cyclopentadienyl group), Ru(CpC₂H₅)₂, Ru(CpC₃H₇)₂, La(CpC₃H₇)₃, Ru(CpC₄H₉)₂, Y(CpC₄H₉)₃ and La(CpC₄H₉)₃. These can be used alone or in a mixture thereof.

Examples of the diketonate compound may include Ba(THD)₂ (wherein, “THD” represents tetramethyl heptanedionate), Sr(THD)₂, La(THD)₃, Pb(THD)₂, Zr(THD)₂, Ba(METHD)₂ (wherein, “METHD” represents methoxyethoxy tetramethyl heptanedionate), Ru(METHD)₃ and Zr(METHD)₄. These can be used alone or in a mixture thereof.

Examples of the alkyl compound may include Al(CH₃)₃, Al(CH₃)₂Cl, Al(CH₃)₂H, Al(C₂H₅)₃, Al(CH₂CH₂(CH₃)₂)₃, Ga(CH₃)₃, Ga(CH₃)₂(C₂H₅), Ga(C₂H₅)₃, Ga(C₂H₅)₂Cl, Ga(CH₂CH₂(CH₃)₂)₃, Ga(CH₂C(CH₃)₃)₃, In(CH₃)₃, ((CH₃)₂(C₂H₅)N)In(CH₃)₃, In(CH₃)₂Cl, In(CH₃)₂(C₂H₅), In(C₂H₅)₃, Sn(CH₃)₄, Sn(C₂H₅)₄, Zn(CH₃)₂, Zn(C₂H₅)₂, Cd(CH₃)₂ and Hg(CH₃)₂. These can be used alone or in a mixture thereof.

The reactant 50 is partially chemisorbed to the substrate 38 after the reactant 50 is introduced into the reaction space 42, thereby forming a preliminary layer on the substrate 38.

Referring to FIGS. 2 and 3B, a plasma is introduced into the reaction space 42 so as to remove a portion of the ligand or an atom of the atomic group of a chemisorbed reactant 50 from the preliminary layer.

In an exemplary embodiment of the present invention, the plasma may be formed using a gas. When the gas is introduced into the buffer space 35 through the gas inlet 31, the RF power is simultaneously applied to the gas so that the gas is excited to form the plasma. That is, as the RF power is applied to the gas, the plasma is formed in the buffer space 35 and then uniformly provided onto the preliminary layer through the showerhead 36.

The gas may include an inert gas, an inactive gas, or a mixture thereof. Since these gases may not be reacted with a non-chemisorbed reactant 50, the gases may effectively remove the ligand or the atom of the chemisorbed reactant 50 without forming impurities. Here, the non-chemisorbed reactant 50 may include a physisorbed reactant 50 to the substrate 38 and/or a drifting reactant 50 in the reaction space 42.

Examples of the inert gas may include a helium (He) gas, a xenon (Xe) gas, a krypton (Kr) gas, an argon (Ar) gas, etc. These can be used alone or in a mixture thereof.

Examples of the inactive gas may include an oxygen (O₂) gas, a hydrogen (H₂) gas, an ammonia (NH₃) gas, a nitrous oxide (N₂O) gas, a nitrogen dioxide (NO₂) gas, etc. These can be used alone or in a mixture thereof.

As described above, the plasma may partially or completely remove the ligand or the atom of the atomic group in the chemisorbed reactant 50 from the preliminary layer. Hence, a layer 52 is completed on the substrate 38. The layer may include a metal, a metal oxide, or a metal nitride.

For example, when the ligands or the atomic groups of the organic metal precursor are completely removed from the preliminary layer except for the metal, a metal layer is formed. In addition, when atoms of hydrocarbon groups in the organic metal precursor such as the alkoxide compound having oxygen (O) are completely removed from the preliminary layer except for the metal and the oxygen (O), a metal oxide layer is formed. Further, when atoms of hydrocarbon groups in the organic metal precursor such as the amino compound having nitrogen (N) are completely removed from the preliminary layer except for the metal and the nitrogen (N), a metal nitride layer is formed.

The plasma may simultaneously remove the non-chemisorbed reactant 50 from the chamber 44 through the gas outlet 39 and the exhaust pipe 41 by operating the pump 40. When the plasma is introduced into the chamber 44, the pressure control valve 43 is closed. After the plasma ventilates the chamber 44, the pressure control valve 43 is opened. Thus, all or substantially all of the non-chemisorbed reactant 50 is removed from the chamber 44 by pumping out the non-chemisorbed reactant 50 from the chamber 44.

Referring to FIGS. 2 and 3C, a layer structure 54 having a desired thickness is formed on the substrate 38 by repeating the introduction of the reactant 50, and removing the ligand or the atomic group from the preliminary layer.

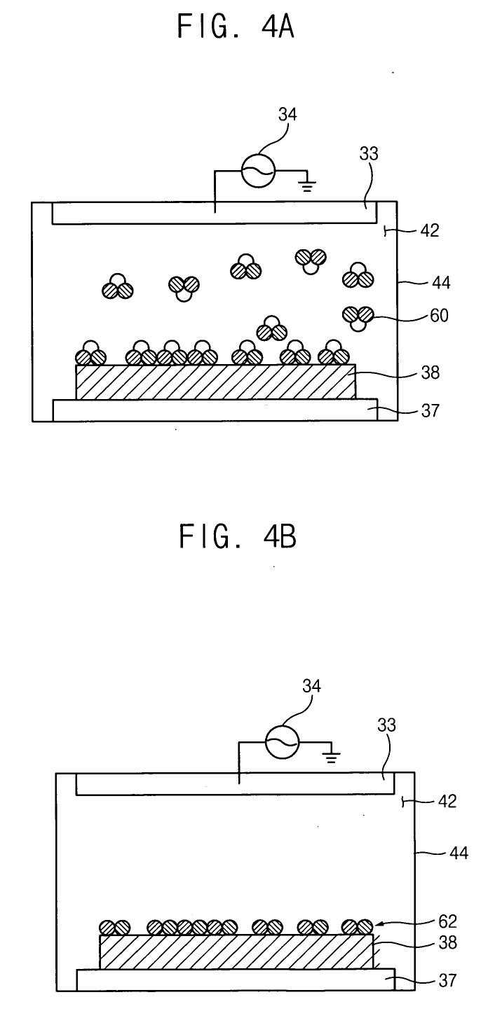

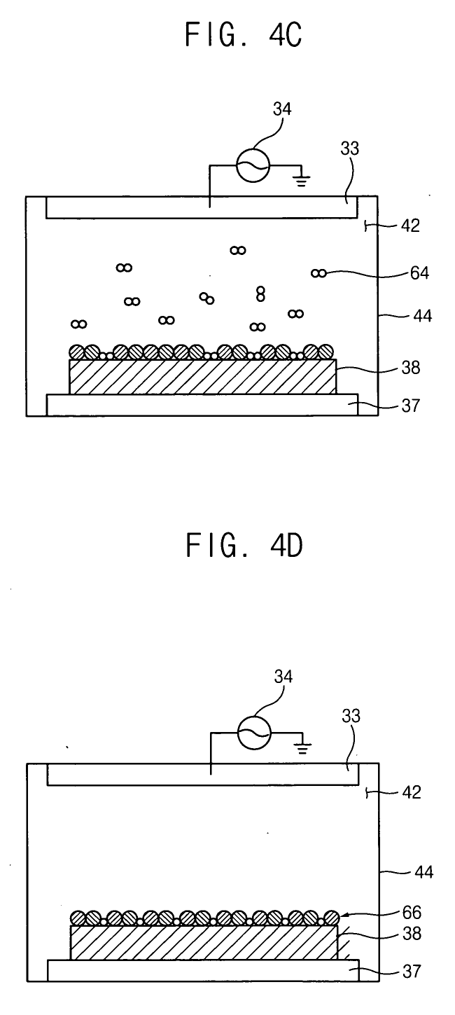

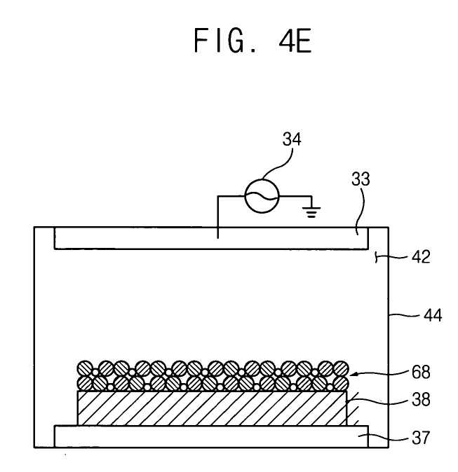

FIGS. 4A to 4E are cross sectional views illustrating a method of forming a layer using the apparatus in FIG. 2 in accordance with an exemplary embodiment of the present invention.

Referring to FIGS. 2 and 4A, the substrate 38 is loaded into the chamber 44, and then a first reactant 60 or a first gas including the first reactant 60 is introduced into the reaction space 42 of the chamber 44 through the gas inlet 31. The first reactant 60 may include an organic precursor.

The first reactant 60 is partially chemisorbed onto the substrate 38 after the first reactant 60 is provided onto the substrate 38 so that an absorption layer is formed on the substrate 38.

In an exemplary embodiment of the present invention, a first purge gas may be introduced into the reaction space 42 of the chamber 44 to remove a non-chemisorbed first reactant 60 from the chamber 44. The non-chemisorbed first reactant 60 may include a physisorbed first reactant 60 to the substrate 38 and/or a drifting first reactant 60 in the chamber 44. The first purge gas and the non-chemisorbed first reactant 60 are exhausted from the chamber 44 through the exhaust pipe 41 by operating the pressure control valve 43 and the pump 40. When the first purge gas removes the non-chemisorbed first reactant 60, the pressure control valve 43 is closed. Then, the pressure valve 43 is opened and the pump 40 is operated so that the first purge gas and the non-chemisorbed first reactant 60 are exhausted from the chamber 44. Here, all or substantially all of the non-chemisorbed first reactant 60 may be removed from the chamber 44.

Referring to FIGS. 2 and 4B, a plasma is introduced into the reaction space 42 so as to remove a portion of the ligand or an atom of the atomic group of a chemisorbed first reactant 60 from the absorption layer.

In an exemplary embodiment of the present invention, the plasma may be formed using a gas. When the gas is introduced into the buffer space 35 through the gas inlet 31, the RF power is simultaneously applied to the gas so that the gas is excited to form the plasma. That is, as the RF power is applied to the gas, the plasma is formed in the buffer space 35 and then uniformly provided onto the absorption layer through the showerhead 36.

The plasma may partially or completely remove the ligand or the atom of the atomic group in the chemisorbed first reactant 60 from the absorption layer so that a preliminary layer 62 is formed on the substrate 38. The preliminary layer 62 may include a metal, a metal oxide, or a metal nitride.

For example, when atoms of hydrocarbon groups in the organic metal precursor such as the alkoxide compound having oxygen (O) are completely removed from the preliminary layer except for the metal and the oxygen (O), a metal oxide layer is formed. In addition, when atoms of hydrocarbon groups in the organic metal precursor such as the amino compound having nitrogen (N) are completely removed from the preliminary layer except for the metal and the nitrogen (N), a metal nitride layer is formed.

The plasma may simultaneously remove the non-chemisorbed first reactant 60 from the chamber 44 through the gas outlet 39 and the exhaust pipe 41 by operating the pump 40. When the plasma is introduced into the chamber 44, the pressure control valve 43 is closed. After the plasma ventilates the chamber 44, the pressure control valve 43 is opened. Thus, all or substantially all of the non-chemisorbed first reactant 60 is removed from the chamber 44 by pumping out the non-chemisorbed first reactant 60 from the chamber 44.

In an exemplary embodiment of the present invention, a second purge gas may be introduced into the reaction space 42 of the chamber 44 to remove the non-chemisorbed first reactant 60 and impurities generated by the plasma from the chamber 44.

A preliminary layer structure having a desired thickness is formed on the substrate 38 by repeating the introduction of the first reactant 50, and removing the ligand or the atomic group from the preliminary layer.

Referring to FIGS. 2 and 4C, a second reactant 64 or a second gas including the second reactant 64 is introduced into the reaction space 42 of the chamber 44. The second reactant 64 may include an oxygen-containing compound or a nitrogen-containing compound. Examples of the second reactant 64 may include oxygen (O₂), nitrous oxide (N₂O), nitrogen (N₂), ammonium (NH₃), etc. These can be used alone or in a mixture thereof.

Referring to FIGS. 2 and 4D, when the second reactant 64 is provided onto the preliminary layer 62, the second reactant 64 is chemically reacted with ingredients in the preliminary layer 62 formed on the substrate 38 to thereby form a layer 66 on the substrate. The layer 66 may include oxynitride.

In an exemplary embodiment of the present invention, the second reactant 64 may have a plasma phase. When a gas-phase second reactant 64 is introduced into the buffer space 35 through the gas inlet 31, the RF power is simultaneously applied to the second reactant 64 so that the second reactant 64 is excited to form a plasma-phase second reactant 64. Thus, reactions between the preliminary layer 62 and the second reactant 64 may be promoted to rapidly form the layer on the substrate 38.

In an exemplary embodiment of the present invention, a third purge gas may be introduced into the reaction space 42 of the chamber 44 to remove any remaining second reactant 64 from the chamber 44. The third purge gas may have a plasma phase. For example, when the third purge gas is introduced into the buffer space 35 through the gas inlet 31, the RF power is simultaneously applied to the third purge gas so that the third purge gas is excited to have the plasma phase.

Referring to FIGS. 2 and 4E, a layer structure 68 having a desired thickness is formed on the substrate 38 by repeating the introduction of the first reactant 50, removing the ligand or the atomic group from the preliminary layer 62, introducing the second reactant 64, and removing the remaining second reactant 64 from the chamber 44.

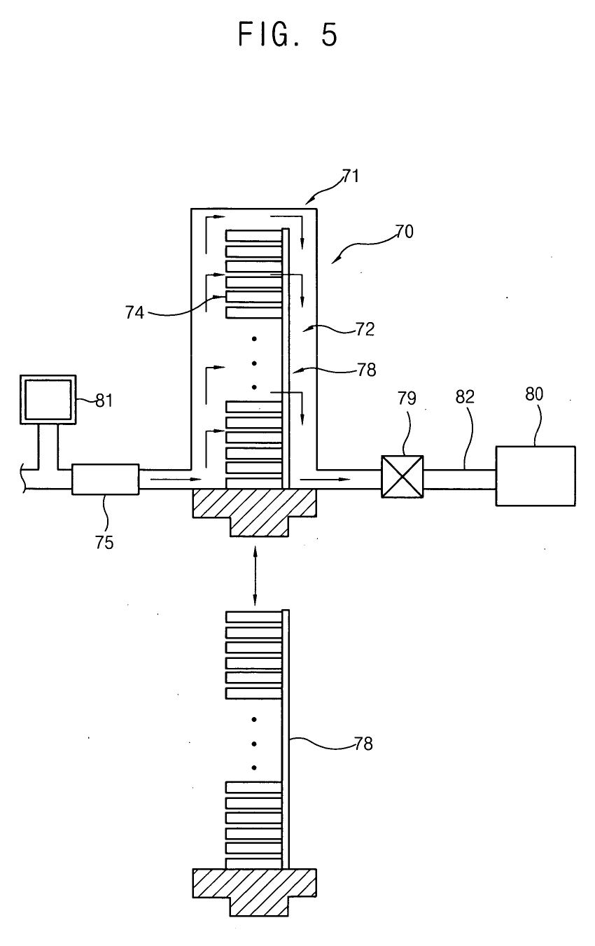

FIG. 5 is a cross sectional view illustrating an apparatus for forming a layer by employing an atomic layer deposition process in accordance with an exemplary embodiment of the present invention.

Referring to FIG. 5, the apparatus includes a chamber 70, a pump 80, a remote plasma generator 81 and a boat 78.

The chamber 70 has a unitary reaction space 72 where a layer is formed on a substrate 74. An element such as a heater installed on a side of the chamber 70 may be omitted for simplicity. The chamber 70 may be a vertical type chamber, which is substantially similar to a conventional LPCVD furnace disclosed in U.S. Pat. Nos. 5,217,340 and 5,112,641. However, another type of the chamber, e.g., a horizontal-type chamber, may be used for forming the layer in accordance with the present invention.

A plurality of substrates 74 or wafers is placed in the reaction space 72 provided in the chamber 70. A series of processes for forming the layer may be sequentially carried out in the reaction space 72.

A boat 78 including the substrates 74 therein is provided under the chamber 70. For example, about twenty to about fifty substrates 74 are loaded in the boat 78. The boat 78 having the substrates 74 is loaded into the chamber 70 and unloaded from the chamber 70 by a transferring member (not shown). For example, the boat 78 is loaded upwardly into the chamber 70 and unloaded downwardly from the chamber 70.

A reactant for forming the layer may be introduced into the chamber 70 through an introducing member 75 connected to one side of the chamber 70. A remote plasma generator 81 is connected to the introducing member 75, and also a gas source (not shown) is connected to the introducing member 75.

A pump 80 for ventilating the chamber 70 is connected to the other side of the chamber 70 through an exhaust pipe 82. A pressure control valve 79 is installed between the pump 80 and the chamber 70.

When the processes for forming the layer are performed in the chamber 70, a bundle of the substrates 74 is loaded into the unitary reaction space 72 of the chamber 70 by the boat 78. For example, about twenty to about fifty substrates 74 may correspond to the bundle of the substrates 74. That is, about twenty to about fifty substrates 74 may be simultaneously processed by an ALD process to form the layers on the substrates 74, respectively. Here, the layers are formed on surfaces of the substrates 74.

The bundle of the substrates 74 is arranged and loaded in the boat 78. The boat 78 typically includes quartz or other materials, and has a plurality of grooves on an inside thereof. The substrates 74 are respectively positioned in the grooves of the boat 78. Since the boat 78 including the bundle of the substrates 74 is loaded into the chamber 70, the bundle of the substrates 74 is simultaneously loaded into the unitary reaction space 72 of the chamber 70.

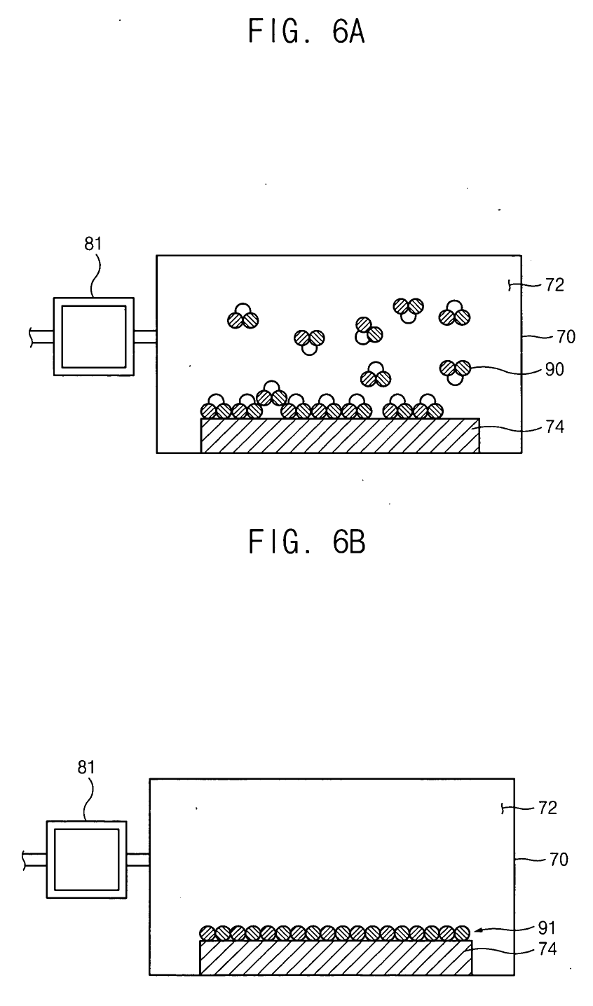

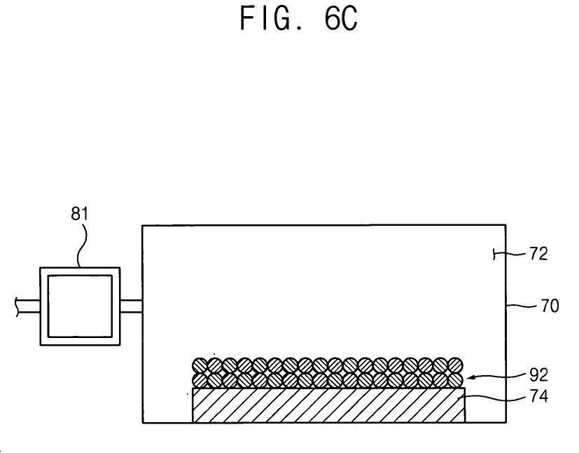

FIGS. 6A to 6C are cross sectional views illustrating a method of forming a layer using the apparatus in FIG. 5. In FIGS. 6A to 6C, the introducing member will be omitted for simplicity.

Referring to FIGS. 5 and 6A, after the substrates 74 are loaded into the chamber 70 by the boat 78, a reactant 90 or a gas including the reactant 90 is introduced into the unitary reaction space 72 of the chamber 70. The reactant 70 is provided into the unitary reaction space 72 of the chamber 70 through the introducing member 75.

The reactant 90 may include an organic precursor such as an organic metal precursor. Here, the reactant 90 may include a metal, and a ligand or an atomic group.

The reactant 90 is partially chemisorbed to the substrate 74 after the reactant 90 is introduced into the reaction space 72, thereby forming a preliminary layer on the substrate 74.

Referring to FIGS. 5 and 6B, plasma is introduced into the reaction space 72 so as to remove a portion of the ligand or an atom of the atomic group of a chemisorbed reactant 90 from the preliminary layer. The plasma is provided from the remote plasma generator 81 into the reaction space 72 of the chamber 70.

The plasma may partially or completely remove the ligand or the atom of the atomic group in the chemisorbed reactant 90 from the preliminary layer. Hence, a layer 91 is formed on the substrate 74. The layer 91 may include a metal, a metal oxide, or a metal nitride.

The plasma may simultaneously remove the non-chemisorbed reactant 90 from the chamber 70 through the exhaust pipe 82 by operating the pump 80. When the plasma is introduced into the chamber 70, the pressure control valve 79 is closed. After the plasma ventilates the chamber 70, the pressure control valve 79 is opened. Thus, all or substantially all of the non-chemisorbed reactant 90 is removed from the chamber 70 by pumping out the non-chemisorbed first reactant 90 from the chamber 70. The non-chemisorbed reactant may include a physisorbed reactant 90 to the substrate 74 and/or a drifting reactant 90 in the chamber 70.

Referring to FIGS. 5 and 6C, a layer structure 92 having a desired thickness is formed on the substrate 74 by repeating introducing the reactant 90, and removing the ligand or the atomic group from the preliminary layer.

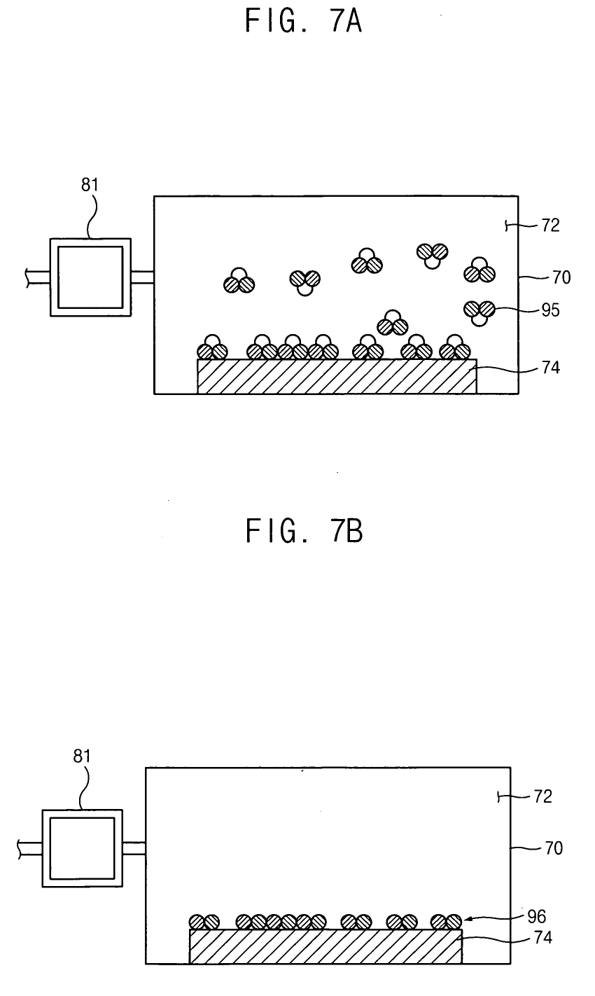

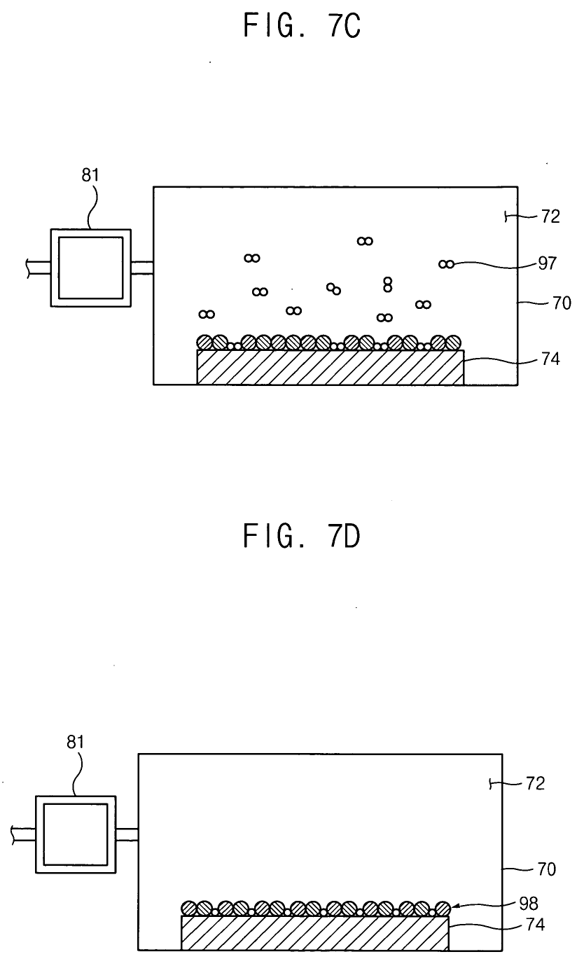

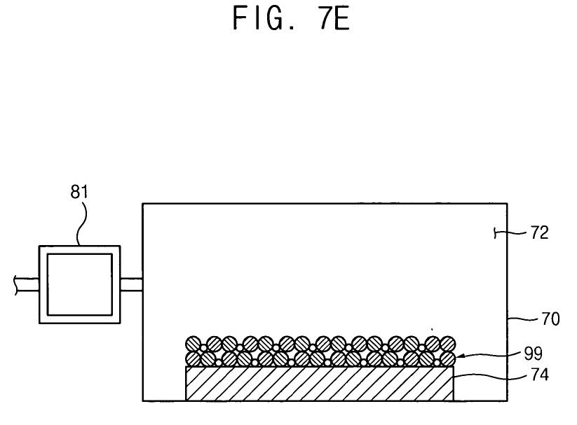

FIGS. 7A to 7E are cross sectional views illustrating a method of forming a layer using the apparatus in FIG. 5 in accordance with an exemplary embodiment of the present invention.

Referring to FIGS. 5 and 7A, the substrate 74 is loaded into the chamber 70, and then a first reactant 95 or a first gas including the first reactant 95 is introduced into the reaction space 72 of the chamber 70 through the introducing member 75. The first reactant 95 may include an organic precursor such as an organic metal precursor. Here, the first reactant 95 may include a metal, and a ligand or an atomic group.

The first reactant 95 is partially chemisorbed onto the substrate 74 after the first reactant 95 is provided onto the substrate 74 so that an absorption layer is formed on the substrate 74.

In an exemplary embodiment of the present invention, a first purge gas may be introduced into the reaction space 72 of the chamber 70 to remove a non-chemisorbed first reactant 95 from the chamber 70. The non-chemisorbed first reactant 95 may include a physisorbed first reactant 95 to the substrate 74 and/or a drifting first reactant 95 in the chamber 70. The first purge gas and the non-chemisorbed first reactant 95 are exhausted from the chamber 70 through the exhaust pipe 82 by operating the pressure control valve 79 and the pump 80. When the first purge gas removes the non-chemisorbed first reactant 95, the pressure control valve 79 is closed. Then, the pressure valve 79 is opened and the pump 80 is operated so that the first purge gas and the non-chemisorbed first reactant 95 are exhausted from the chamber 70. Here, all or substantially all of the non-chemisorbed first reactant 95 may be removed from the chamber 70.

Referring to FIGS. 5 and 7B, plasma is introduced into the reaction space 72 so as to remove a portion of the ligand or an atom of the atomic group of a chemisorbed first reactant 95 from the absorption layer.

In an exemplary embodiment of the present invention, the plasma may be introduced from the remote plasma generator through the introducing member 75.

The plasma may partially or completely remove the ligand or the atom of the atomic group in the chemisorbed first reactant 95 from the absorption layer so that a preliminary layer 96 is formed on the substrate 74. The preliminary layer 96 may include a metal, a metal oxide, and a metal nitride.

The plasma may simultaneously remove the non-chemisorbed first reactant 95 from the chamber 70 through exhaust pipe 82 by operating the pump 80. When the plasma is introduced into the chamber 70, the pressure control valve 79 is closed. After the plasma ventilates the chamber 70, the pressure control valve 79 is opened. Thus, all or substantially all of the non-chemisorbed first reactant 95 is removed from the chamber 70 by pumping out the non-chemisorbed first reactant 95 from the chamber 70.

In an exemplary embodiment of the present invention, a second purge gas may be introduced into the reaction space 72 of the chamber 70 to remove the non-chemisorbed first reactant 95 and impurities generated by the plasma from the chamber 70.

A preliminary layer structure having a desired thickness is formed on the substrate 74 by repeating the introduction of the first reactant 95, and removing the ligand or the atomic group from the preliminary layer.

Referring to FIGS. 5 and 7C, a second reactant 97 or a second gas including the second reactant 97 is introduced into the reaction space 72 of the chamber 70. The second reactant 97 may include an oxygen (O)-containing compound or a nitrogen (N)-containing compound.

Referring to FIGS. 5 and 7D, when the second reactant 97 is provided onto the preliminary layer, the second reactant 97 is chemically reacted with the reactants in the preliminary layer formed on the substrate 74 to thereby form a layer 98 on the substrate 74. The layer 98 may include oxynitide.

In an exemplary embodiment of the present invention, the second reactant 97 may have a plasma phase. In particular, a plasma-phase second reactant 97 is introduced from the remote plasma generator 81 into the chamber 70. Thus, reactions between the preliminary layer and the second reactant 97 may be promoted to rapidly form the layer 98 on the substrate 74.

In an exemplary embodiment of the present invention, a third purge gas may be introduced into the reaction space 72 of the chamber 70 to remove a remaining second reactant 97 from the chamber 70. The third purge gas may have a plasma phase. For example, the third purge gas having a plasma phase may be introduced from the remote plasma generator 81 into the chamber 70.

Referring to FIGS. 5 and 7E, a layer structure 99 having a desired thickness is formed on the substrate 74 by repeating the introduction of the first reactant 95, removing the ligand or the atomic group from the preliminary layer, introducing the second reactant 97, and removing the remaining second reactant 97 from the chamber 70.

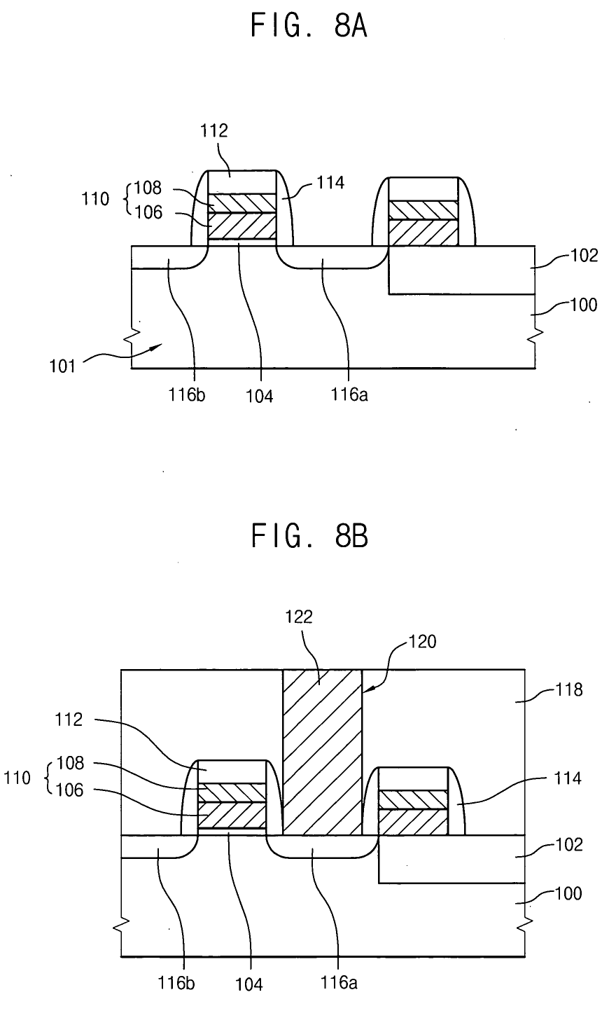

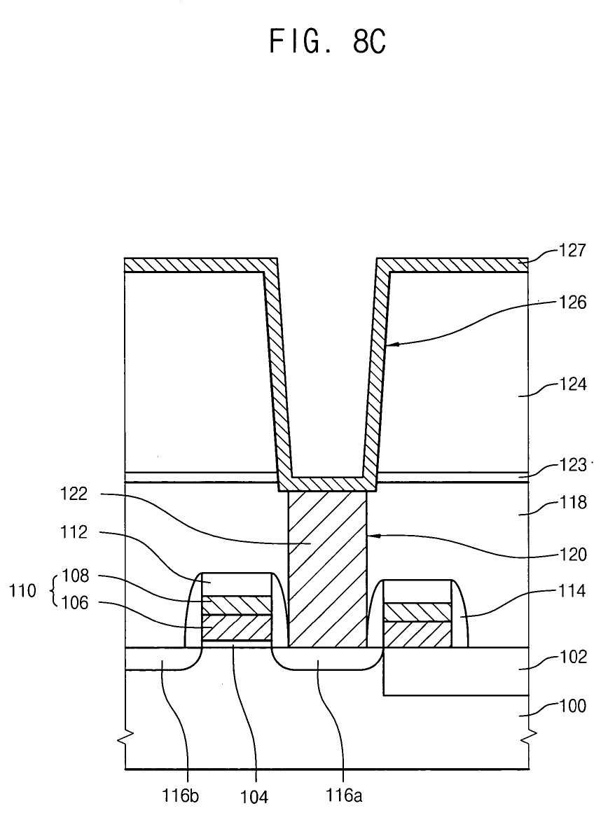

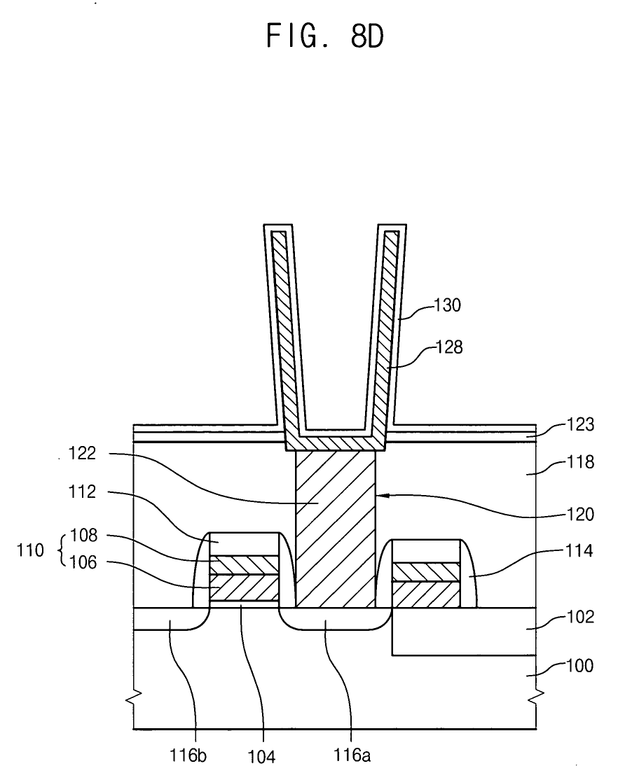

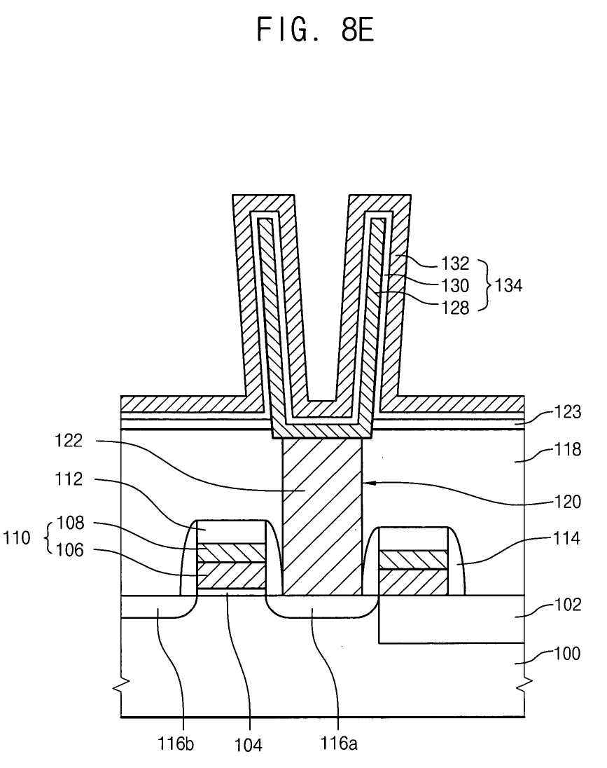

FIGS. 8A to 8E are cross sectional views illustrating a method of forming a capacitor of a semiconductor device in accordance with an exemplary embodiment of the present invention.

Referring to FIG. 8A, an active region 101 and a field region 102 are defined on a semiconductor substrate 100 by an isolation process such as a shallow trench isolation (STI) process.

A transistor including a gate insulation layer 104, a gate electrode 110 and source/drain regions 116a and 116b is formed on the substrate 100. When a semiconductor device has a memory capacity of about 1 gigabit or more, the gate insulation layer 104 may have a thickness of about 10 Å or less.

The gate insulation layer 104 may be formed using an ALD process. In particular, an insulation layer is formed by processes substantially identical to the processes described with reference to FIGS. 3A to 3C, FIGS. 4A to 4E, FIGS. 6A to 6C or FIGS. 7A to 7E. Hence, the gate insulation layer 104 including metal oxide, metal nitride or metal oxynitride may be completed on the substrate 100. The gate electrode 110 may have a polycide structure including a doped polysilicon layer 106 and a metal silicide layer 108.

A capping layer 112 and a spacer 114 are formed on an upper face and a sidewall of the gate electrode 110, respectively. The capping layer 112 and the spacer 114 may include silicon oxide or silicon nitride.

Referring to FIG. 8B, a first insulation layer 118 is formed on the substrate 100 on which the transistor is formed. The first insulation layer 118 may include oxide. A contact hole 120 partially exposing the source/drain regions 116a and 116b is formed by partially etching the first insulation layer 118 using a photolithography process. Then, a contact plug 122 is formed in the contact hole 120 by depositing polysilicon doped with phosphorous (P) after a first conductive layer is formed on the first insulation layer 118 to fill up the contact hole 120 and partially removing the first conductive layer. Here, an upper portion of the first conductive layer is removed using an etch back process or a chemical mechanical polishing (CMP) process to thereby form the contact plug 122 in the contact hole 120.

Referring to FIG. 8C, an etch stop layer 123 is formed on the contact plug 122 and the first insulation layer 118. The etch stop layer 123 may include a material having a high etching selectivity with respect to the first insulation layer 118. For example, the etch stop layer 123 may include silicon nitride or silicon oxynitride.

A second insulation layer 124, typically including oxide, is formed on the etch stop layer 123, and then partially etched to form an opening 126 to expose the contact plug 122. In particular, the second insulation layer 124 is partially etched until the etch stop layer 123 is exposed. Then, the etch stop layer 123 is partially etched to form the opening 126 that exposes the contact plug 122 and a portion of the first insulation layer 118 around the contact plug 122. The opening 126 may be formed with an inclination resulting from a bottom portion of the opening 126 being formed narrower than an upper portion thereof. This shape may be obtained in part due to a loading effect during the etch process in which the etch rate at the bottom portion is slower than that at the upper portion of the opening 126.

A second conductive layer 127 is formed on the sidewalls and the bottom portion of the opening 126, and on the second insulation layer 124. The second conductive layer 127 may include a conductive material such as doped polysilicon, a metal such as ruthenium (Ru), platinum (Pt) and iridium (Ir), a conductive metal nitride such as titanium nitride (TiN), tantalum nitride (TaN) and tungsten nitride (WN), or a composition of two or more of these materials.

Referring to FIG. 8D, a sacrificial layer (not shown) is formed on the second conductive layer 127 and the opening 126. An upper portion of the sacrificial layer is then etched back so that the second conductive layer 127 may remain on the sidewall and the bottom portion of the opening 126. The second conductive layer 127 formed on the second insulation layer 124 is removed. The second conductive layer 127 formed along the profile of the inner portion of the opening 126 is then separated with the cell unit to form a lower electrode 128 of a capacitor at each cell region. Then, the sacrificial layer may be removed using a wet etching process. The lower electrode 128 may be formed to have a generally cylindrical shape in which an inlet portion is relatively wide and a bottom portion is relatively narrow.

Subsequently, a preliminary layer (not shown) is formed on the lower electrode 128 using an organic precursor such as an alkoxide compound, an amino compound, a cyclopentadienyl compound, a diketonate compound, and an alkyl compound as a reactant by processes substantially identical to the processes described with reference to FIGS. 3A to 3C and FIGS. 6A to 6C. Plasma generated from an inert gas or an inactive gas is then provided onto the preliminary layer to form a dielectric layer 130. Particularly, ligands or atomic groups in the preliminary layer are removed from the preliminary layer by the plasma to complete the dielectric layer 130 of the capacitor. The dielectric layer 130 may include metal oxide or metal nitride.

In an exemplary embodiment of the present invention, an absorption layer (not shown) is formed on the lower electrode 128 using an organic precursor as a first reactant by processes substantially identical to the processes described with reference to FIGS. 4A to 4E and FIGS. 7A to 7E. Subsequently, plasma generated from an inert gas or an inactive gas is then provided onto the absorption layer to form a preliminary layer. Particularly, ligands or atomic groups in the absorption layer are removed from the absorption layer by the plasma to form the preliminary layer. An oxygen-containing compound or a nitrogen-containing compound such as oxygen (O₂), nitrous oxide (N₂O), nitrogen (N₂), or ammonia (NH₃) as a second reactant is then provided onto the preliminary layer to complete a dielectric layer 130. The dielectric layer may include metal oxynitride.

The dielectric layer 130 may be formed as a single layer or may be formed as a composite layer including two or more layers of metal oxides that are alternately deposited. For example, the dielectric layer 130 may be formed by alternately depositing the layers of Al₂O₃ and HfO₂ according to changes of the precursors introduced into the chamber during the ALD process.

Referring to FIG. 8E, when an upper electrode 132 is formed on the dielectric layer 130, a capacitor 134 including the lower electrode 128, the dielectric layer 130 and the upper electrode 132 is formed over the substrate 100. The upper electrode 132 may be formed using a conductive material that includes polysilicon, a metal such as ruthenium (Ru), platinum (Pt) and iridium (Ir), or a conductive metal nitride such as TiN, TaN and WN. Alternatively, the upper electrode may include at least one layer formed using a compound of the conductive materials. For example, the upper electrode 132 has a stacked structure in which a polysilicon layer is formed on the dielectric layer 130 and a titanium nitride layer is formed on the polysilicon layer.

Preparation of a Hafnium Oxynitride Layer

A hafnium oxynitride layer was prepared according to an exemplary embodiment of the present invention. That is, the hafnium oxynitride layer was formed on a substrate using an atomic layer deposition process. TEMAH (tetrakis(ethylmethylamino)hafnium) gas was used as a first reactant to form an absorption layer, and then the absorption layer was treated using an argon plasma to form a preliminary layer. Subsequently, oxygen (O₂) as a second reactant was provided on to the preliminary layer to form the hafnium oxynitride layer. The hafnium oxynitride layer was formed under a pressure of about 200 mTorr at a temperature of about 325° C. A flow rate of the first reactant was about 1000 sccm.

Particularly, the substrate was loaded into a chamber. The TEMAH as the first reactant was introduced into the chamber for about 2 seconds to chemisorb the TEMAH to the substrate. Subsequently, a non-chemisorbed TEMAH was removed from the chamber, and hydrocarbon groups except nitrogens in chemisorbed TEMAH were simultaneously removed from the TEMAH using the argon plasma. The argon plasma was then provided into the chamber for about 2 seconds. As described above, introducing the TEMAH and providing the argon plasma were repeatedly performed for about 90 times to form the preliminary layer including hafnium nitride.

Then, the preliminary layer on the substrate was oxidized for about 24 hours. Accordingly, the hafnium oxynitride layer having a thickness of about 140 Å was formed on the substrate.

Estimation of an Oxygen (O) Content in a Hafnium Oxynitride Layer

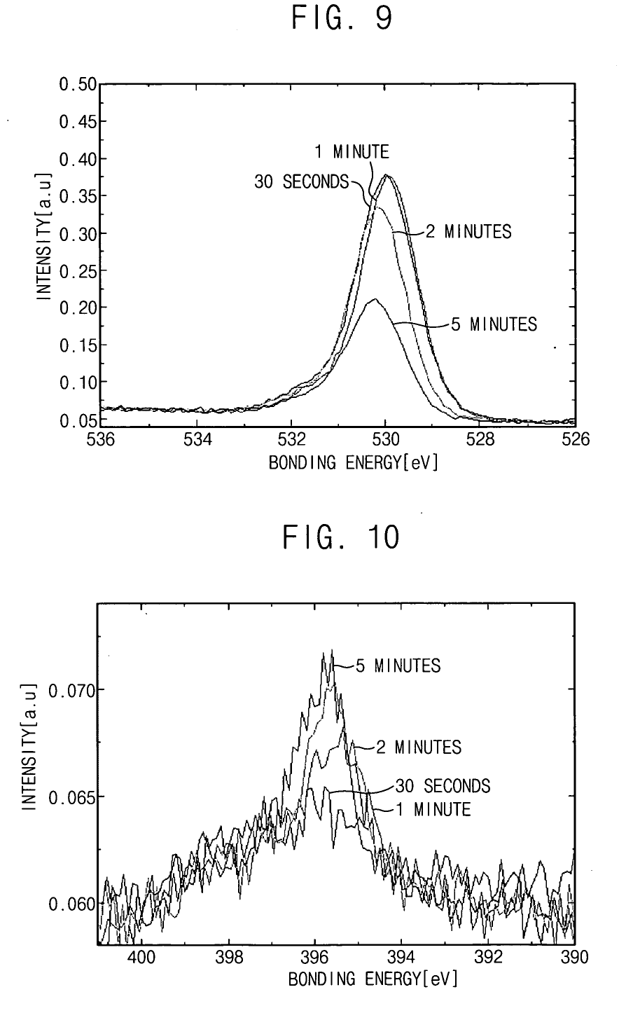

FIG. 9 is a graph illustrating the oxygen content of a hafnium oxynitride layer obtained using an X-ray photoemission spectroscopy method. The oxygen content may be identified from the hafnium-oxygen bond in the hafnium oxynitride layer. In FIG. 9, as the maximum peak value becomes higher, the oxygen content of the hafnium oxynitride layer becomes greater.

After respectively sputtering an argon plasma to the hafnium oxynitride layer for about 30 seconds, 1 minute, 2 minutes, and 5 minutes, the oxygen content of the hafnium oxynitride layer was measured. As the sputtering time becomes longer, the lower portion of the hafnium oxynitride layer may be exposed.

Referring to FIG. 9, as the sputtering time increases, the oxygen content of the hafnium oxynitride layer reduces. That is, the oxygen content of the lower portion of the hafnium oxynitride layer may be smaller than that of an upper portion thereof.

Estimation of a Nitrogen (N) Content in a Hafnium Oxynitride Layer

FIG. 10 is a graph illustrating the nitrogen content of a hafnium oxynitride layer obtained using an X-ray photoemission spectroscopy method. The nitrogen content may be identified from the hafnium-nitrogen bond in the hafnium oxynitride layer. In FIG. 10, as the maximum peak value becomes higher, the nitrogen content of the hafnium oxynitride layer becomes greater.

After respectively sputtering an argon plasma to the hafnium oxynitride layer for about 30 seconds, 1 minute, 2 minutes, and 5 minutes, the nitrogen content of the hafnium oxynitride layer was measured. As the sputtering time becomes longer, a lower portion of the hafnium oxynitride layer may be exposed.

Referring to FIG. 10, as the sputtering time is longer, the nitrogen content of the hafnium oxynitride layer increases. That is, the nitrogen content of the lower portion of the hafnium oxynitride layer may be greater than that of the upper portion thereof.

Referring to FIGS. 9 and 10, the upper portion of the hafnium oxynitride layer includes a relatively large amount of oxygen (O), and the lower portion thereof includes a relatively large amount of nitrogen (N). According to the present invention, introducing the first reactant and providing the argon plasma were repeatedly performed to form a preliminary layer. Then, the preliminary layer was oxidized to form the hafnium oxynitride layer. Here, when the preliminary layer was oxidized, an upper portion of the preliminary layer may be more rapidly oxidized than a lower portion thereof. Thus, the lower portion of the hafnium oxynitride layer may exhibit hafnium nitride layer characteristics more greatly than the upper portion thereof.

Accordingly, the preliminary layer may include the hafnium nitride, and the hafnium oxynitride layer is formed by oxidizing the preliminary layer. That is, the hafnium nitride layer as the preliminary layer may be formed by introducing the first reactant, and providing the argon plasma. Then, the hafnium nitride layer may be oxidized by providing oxygen to the hafnium nitride layer to form the hafnium oxynitride layer.

Estimation of Contents of Hf—N and Hf—O bonds in a Hafnium Oxynitride Layer

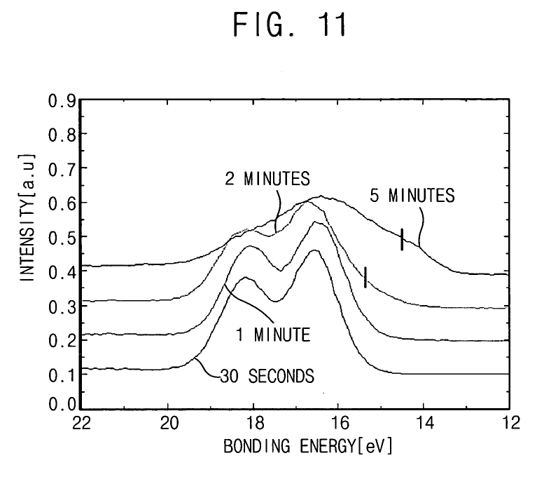

FIG. 11 is a graph illustrating contents of Hf—N and Hf—O bonds in a hafnium oxynitride layer obtained using an X-ray photoemission spectroscopy method.

After respectively sputtering an argon plasma to the hafnium oxynitride layer for about 30 seconds, 1 minute, 2 minutes, and 5 minutes, the content of Hf—N and Hf—O bonds in the hafnium oxynitride layer was measured. As the sputtering time becomes longer, a lower portion of the hafnium oxynitride layer may be exposed.

Referring to FIG. 11, as the sputtering time is longer, the maximum peak value representing the Hf—O bond changes into that representing the Hf—N bond.

The upper portion of the hafnium oxynitride layer includes a relatively large amount of oxygen (O), and the lower portion thereof includes a relatively large amount of nitrogen (N). According to the present invention, introducing the first reactant and providing the argon plasma were repeatedly performed to form a preliminary layer. Then, the preliminary layer was oxidized to form the hafnium oxynitride layer. Here, when the preliminary layer was oxidized, an upper portion of the preliminary layer may be more rapidly oxidized than a lower portion thereof. Thus, the lower portion of the hafnium oxynitride layer may exhibit hafnium nitride layer characteristics more greatly than the upper portion thereof.

Accordingly, the preliminary layer may include the hafnium nitride, and the hafnium oxynitride layer is formed by oxidizing the preliminary layer.

According to the present invention, a plasma is provided to a preliminary layer formed using an atomic layer deposition process to partially remove atoms from the preliminary layer. Hence, a desired layer may be economically formed from the preliminary layer.

Thus, processes for forming the desired layer may be simplified. As a result, a highly integrated semiconductor device having improved reliability may be economically manufactured so that time and costs required for the manufacturing of the semiconductor device may be reduced.

Although exemplary embodiments of the present invention have been described, it is understood that the present invention should not be limited to these exemplary embodiments but various changes and modifications can be made by one skilled in the art within the spirit and scope of the present invention as hereinafter claimed.

What is claimed is:

1. A method of forming a layer comprising:
forming a preliminary layer comprising atoms on a substrate by an atomic layer deposition (ALD) process; and
partially removing the atoms from the preliminary layer using a plasma, the plasma being formed from a gas.

2. The method of claim 1, wherein the plasma is generated adjacent to the substrate.

3. The method of claim 1, wherein the plasma is generated separate from the substrate.

4. The method of claim 1, wherein the gas includes an inert gas, an inactive gas or a mixture thereof.

5. The method of claim 4, wherein the inert gas includes at least one gas selected from the group consisting of a helium (He) gas, a xenon (Xe) gas, a krypton gas (Kr), and an argon (Ar) gas.

6. The method of claim 4, wherein the inactive gas includes at least one gas selected from the group consisting of an oxygen gas (O₂), a hydrogen (H₂) gas, an ammonia (NH₃) gas, a nitrous oxide gas (N₂O), and a nitrogen dioxide (NO₂) gas.

7. The method of claim 1, wherein the layer includes metal, metal oxide, or metal nitride.

8. A method of forming a layer comprising:
chemisorbing a reactant to a substrate; and
partially removing atoms from a chemisorbed reactant using a plasma.

9. The method of claim 8, wherein the reactant includes an organic metal compound.

10. The method of claim 9, wherein the organic metal compound includes at least one compound selected from the group consisting of an alkoxide compound, an amino compound, a cyclopentadienyl compound, a diketonate compound and an alkyl compound.

11. The method of claim 10, wherein the alkoxide compound includes at least one compound selected from the group consisting of B[OCH₃]₃, B[OC₂H₅]₃, Al[OCH₃]₃, Al[OC₂H₅]₃, Al[OC₃H₇]₃, Ti[OCH₃]₄, Ti[OC₂H₅]₄, Ti[OC₃H₇]₄, Zr[OC₃H₇]₄, Zr[OC₄H₉]₄, Zr[OC₄H₈OCH₃]₄, Hf[OC₄H₉]₄, Hf[OC₄H₈OCH₃]₄, Hf[OSi(C₂H₅)₃]₄, Hf[OC₂H₅]₄, Hf[OC₃H₇]₄, Hf[OC₄H₉]₄, Hf[OC₅H₁₁]₄, Si[OCH₃]₄, Si[OC₂H₅]₄, Si[OC₃H₇]₄, Si[OC₄H₉]₄, HSi[OCH₃]₃, HSi[OC₂H₅]₃, Si[OCH₃]₃F, Si[OC₂H₅]₃F, Si[OC₃H₇]₃F, Si[OC₄H₉]₃F, Sn[OC₄H₉]₄, Sn[OC₃H₇]₃[C₄H₉], Pb[OC₄H₉]₄, Pb₄O[OC₄H₉]₆, Nb[OCH₃]₅, Nb[OC₂H₅]₅, Nb[OC₃H₇]₅, Nb[OC₄H₉]₅, Ta[OCH₃]₅, Ta[OC₂H₅]₅, Ta[OC₄H₉]₅, Ta[OC₂H₅]₅, Ta[OC₂H₅]₅[OC₂H₄N(CH₃)₂], P[OCH₃]₃, P[OC₂H₅]₃, P[OC₃H₇]₃, P[OC₄H₉]₃ and PO[OCH₃]₃.

12. The method of claim 10, wherein the amino compound includes at least one compound selected from the group consisting of Hf(NCH₃CH₃)₄, Hf(NCH₃C₂H₅)₄, Hf(NC₂H₅C₂H₅)₄, Hf(NCH₃C₃H₇)₄, Hf(NC₂H₅C₃H₇)₄ and Hf(NC₃H₇C₃H₇)₄.

13. The method of claim 10, wherein the cyclopentadienyl compound includes at least one compound selected from the group consisting of Ru(Cp)₂ (wherein, “Cp” represents a cyclopentadienyl group), Ru(CpC₂H₅)₂, Ru(CpC₃H₇)₂, La(CpC₃H₇)₃, Ru(CpC₄H₉)₂, Y(CpC₄H₉)₃ and La(CpC₄H₉)₃.

14. The method of claim 10, wherein the diketonate compound includes at least one compound selected from the group consisting of Ba(THD)₂ (wherein, “THD” represents tetramethyl heptanedionate), Sr(THD)₂, La(THD)₃, Pb(THD)₂, Zr(THD)₂, Ba(METHD)₂ (wherein, “METHD” represents methoxyethoxy tetramethyl heptanedionate), Ru(METHD)₃ and Zr(METHD)₄.

15. The method of claim 10, wherein the alkyl compound includes at least one compound selected from the group consisting of Al(CH₃)₃, Al(CH₃)₂Cl, Al(CH₃)₂H, Al(C₂H₅)₃, Al(CH₂CH₂(CH₃)₂)₃, Ga(CH₃)₃, Ga(CH₃)₂(C₂H₅), Ga(C₂H₅)₃, Ga(C₂H₅)₂Cl, Ga(CH₂CH₂(CH₃)₂)₃, Ga(CH₂C(CH₃)₃)₃, In(CH₃)₃, ((CH₃)₂(C₂H₅)N)In(CH₃)₃, In(CH₃)₂Cl, In(CH₃)₂(C₂H₅), In(C₂H₅)₃, Sn(CH₃)₄, Sn(C₂H₅)₄, Zn(CH₃)₂, Zn(C₂H₅)₂, Cd(CH₃)₂ and Hg(CH₃)₂.

16. A method of forming a layer comprising:
loading a substrate into a chamber;
introducing a reactant into the chamber;
chemisorbing the reactant to the substrate to form a preliminary layer on the substrate; and
partially removing atoms from the preliminary layer using a plasma.

17. The method of claim 16, further comprising removing a non-chemisorbed reactant from the chamber using the plasma while removing the atoms from the preliminary layer.

18. The method of claim 16, wherein introducing the reactant, chemisorbing the reactant and removing the atoms are repeatedly performed at least once.

19. A method of forming a layer comprising:
loading a substrate into a chamber;
introducing a first reactant into the chamber;
chemisorbing the first reactant to the substrate to form an absorption layer on the substrate;
partially removing atoms from the absorption layer using a plasma to form a preliminary layer on the substrate; and
introducing a second reactant into the chamber to form a layer on the substrate.

20. The method of claim 19, wherein the layer includes metal oxynitride.

21. The method of claim 19, wherein the second reactant includes an oxygen (O)-containing compound or a nitrogen (N)-containing compound.

22. The method of claim 19, wherein the second reactant has a plasma phase.

23. The method of claim 19, further comprising introducing a purge gas into the chamber to remove a non-chemisorbed first reactant from the chamber before removing the atoms from the absorption layer.

24. The method of claim 19, further comprising introducing a purge gas into the chamber to remove a non-chemisorbed first reactant and impurities generated by the plasma from the chamber before introducing the second reactant.

25. The method of claim 19, wherein introducing the first reactant, chemisorbing the first reactant and removing the atoms are repeatedly performed at least once before introducing the second reactant.

26. The method of claim 19, wherein introducing the first reactant, chemisorbing the first reactant, removing the atoms and introducing the second reactant are repeatedly performed at least once.

27. The method of claim 19, further comprising introducing a purge gas into the chamber to remove an unreacted second reactant from the chamber after introducing the second reactant.

28. The method of claim 27, wherein the purge gas has a plasma phase.

29. A method of forming a capacitor of a semiconductor device comprising:
loading a substrate including a lower electrode into a chamber;
providing a reactant onto the substrate to form a preliminary layer on the lower electrode;
partially removing atoms from the preliminary layer to form a dielectric layer on the lower electrode; and
forming an upper electrode on the dielectric layer.

30. The method of claim 29, wherein each of the lower and the upper electrodes includes a silicon compound, metal, metal oxide, metal nitride or metal oxynitride.

31. A method of forming a capacitor of a semiconductor device comprising:
loading a substrate including a lower electrode into a chamber;
providing a first reactant onto the substrate to form an absorption layer on the lower electrode;
partially removing atoms from the absorption layer to form a preliminary layer on the lower electrode;
providing a second reactant onto the preliminary layer to form a dielectric layer on the lower electrode; and
forming an upper electrode on the dielectric layer.
